(19) United States
(12) Patent Application Publication
(10) Pub. No.: US 2003/0003772 A1
(43) Pub. Date: Jan. 2, 2003

(54) Method of manufacturing semiconductor device having insulating film

(75) Inventors: Yasuhiro Hibi, Hyogo (JP); Satoshi Shimizu, Hyogo (JP); Naoki Tsuji, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/178,558

(22) Filed: Jun. 25, 2002

(30) Foreign Application Priority Data
Jun. 28, 2001 (JP) 2001-195706(P)

(51) Int. Cl. H01L 21/336

(52) U.S. Cl. 438/787

(57) ABSTRACT

There is obtained a method of manufacturing a semiconductor device capable of preventing deterioration in electrical characteristic thereof. The method includes a step of forming the step section on the main surface of the semiconductor substrate and a step of forming the oxide film on the main surface of the semiconductor substrate using an active oxygen.

### BACKGROUND OF THE INVENTION

1. Field of the Invention

The present invention relates to a method of manufacturing a semiconductor device, and more particularly, to a method of manufacturing a semiconductor device capable of improving an electrical characteristic thereof.

2. Description of the Background Art

In the prior art, there was known a non-volatile semiconductor memory device such as a flash memory as one of semiconductor devices. FIG. 20 is a schematic sectional view showing a prior art non-volatile semiconductor memory device. FIG. 21 is a schematic partly enlarged sectional view of the non-volatile semiconductor memory device shown in FIG. 20. Description will be given of a prior art non-volatile semiconductor memory device with reference to FIGS. 20 and 21.

Referring to FIGS. 20 and 21, an element formation region of a semiconductor substrate 101 is a region surrounded with an isolation insulating film 102, including a region having a flat top surface and a region that is a boundary portion abutting on the isolation insulating film 102, where a step section 115 is formed. In the element formation region, a tunnel oxide film 103 is formed on a main surface of semiconductor substrate 101. Tunnel oxide film 103 is formed so as to cover the flat portion of the main surface of semiconductor substrate 101 and in addition, extend over step section 115. A peripheral edge portion 117 of tunnel oxide film 103 on step section 115 is thinner than a portion of tunnel oxide film 103 on the flat top surface in the element formation region.

A floating gate electrode 104a is formed so as to cover the tunnel oxide film 103 and extend to near the top of isolation insulating film 102. Furthermore, a tunnel oxide film, though not shown, is also formed on regions opposite to the region where tunnel oxide film 103 is formed with isolation insulating film 102 interposing therebetween on the main surface of semiconductor substrate 101 and floating gate electrodes 104b and 104c are formed on the tunnel oxide film.

An ONO film 105 is formed on floating gate electrode 104a to 104c. ONO film 105 is a stacked film composed of a lower layer oxide film, a nitride film formed on the lower layer oxide film, and an upper layer oxide film formed on the nitride film. A polysilicon film 106 is formed on ONO film 105. A Tungsten silicide film 107 is formed on polysilicon film 106. A control gate electrode is constituted of polysilicon film 106 and tungsten silicide film 107. An oxide film 108 formed using a CVD (Chemical Vapor Deposition) method is layered on tungsten silicide film 107.

Note that on the main surface of semiconductor substrate 101, a source region and drain region are formed at opposite positions with the region where the tunnel oxide film 103 is formed interposing therebetween in a direction normal to the sheet of FIG. 20.

FIGS. 22 to 25 are schematic sectional views for describing a method of manufacturing the non-volatile semiconductor memory device shown in FIGS. 20 and 21. Description will be given of a method of manufacturing the semiconductor device shown in FIGS. 20 and 21 with reference to FIGS. 22 to 25.

First of all, a silicon oxide film 111 (see FIG. 22) is formed on the main surface of semiconductor substrate 101 (see FIG. 22). A silicon nitride film 112 (see FIG. 22) is formed on silicon oxide film 111. A resist film having a pattern for openings is formed on silicon nitride film 112 with the openings on regions where isolation insulating films 102 (see FIG. 20) are formed, using a photolithographic processing technique.

Then, silicon nitride film 112 and silicon oxide film 111 are partly removed by etching using the resist film as a mask. As a result, openings 114 (see FIG. 22) are formed in silicon nitride film 112 and silicon oxide film 111. Thereafter, the resist film is removed. A resulting structure is as shown in FIG. 22. Note that in the above etching step, the top surface of semiconductor substrate 101 is also partly removed at the bottom of opening 114.

Thereafter, as shown in FIG. 23, an exposed surface of semiconductor substrate 101 at the bottom of opening 114 is subjected to oxidation, thereby forming an isolation insulating film 102. At this time, since isolation insulating film 102, as shown in FIG. 23, grows up into under a lower end portion of silicon nitride film 112, the lower end portion of silicon nitride film 112 is shaped so as to sit on an upper end portion of isolation insulating film 102. Thereafter, the silicon nitride film 112 (see FIG. 23) having been used as a mask is removed.

Then, as shown in FIG. 24, silicon oxide film 111 (see FIG. 23) is removed using wet etching. At this time, a top surface layer of insulating film 102 is partly removed by wet etching simultaneously with part of silicon oxide film 111. For this reason, as shown in FIG. 24, with removal of the surface layer of isolation insulating film 102, step sections 115 are formed at a peripheral edge portion of the element formation region of semiconductor substrate 101. The etching for removing silicon oxide film 111 is continued to a height of step section 115 above isolation insulating film 102 of the order of 10 nm.

Thereafter, there is formed a sacrifice oxide film (not shown) for protecting the main surface of semiconductor substrate 101, followed by implantation of conductive impurities for forming a source region, a drain region and so on into the main surface of semiconductor substrate 101. After implantation of the conductive impurities, the sacrifice oxide film is removed by wet etching.

Then, as shown in FIG. 25, tunnel oxide film 103 is formed on the element formation region located between isolation insulating films 102 on the main surface of semiconductor substrate 101 using a wet oxidation method or the like method. At this time, tunnel oxide film 103 in a region on the step section 115 is thinner than in the other region thereof.

Thereafter, sequentially formed on tunnel oxide film 103 are floating gate electrodes 104a to 104c, ONO film 105, polysilicon film 106, tungsten silicide film 107 and oxide film 108 in that order, thus obtaining the non-volatile semiconductor memory device shown in FIGS. 20 and 21.

As other prior art examples of non-volatile semiconductor memory device, there can be presented a non-volatile semiconductor memory device of a structure as shown in FIG. 26.

FIG. 26 is a schematic sectional view showing another example of prior art non-volatile semiconductor memory device. FIG. 26 corresponds to FIG. 20. Description will be given of another example of prior art non-volatile semiconductor memory device with reference to FIG. 26.

Referring to FIG. 26, the non-volatile semiconductor memory device has a structure fundamentally similar to that of the non-volatile semiconductor memory device shown in FIGS. 20 and 21, with a difference in structure of an element isolation region therebetween. That is, while in the non-volatile semiconductor memory device shown in FIGS. 20 and 21, isolation insulating film 102 formed using a so-called LOCOS method is provided; in the non-volatile semiconductor memory device shown in FIG. 26, a so-called trench isolation structure is adopted in the element isolation region.

That is, trenches 118 are formed so as to abut on the element formation region of a semiconductor substrate 101. A nitride region 119 is formed in semiconductor substrate 101 constituting a sidewall surface and bottom surface of trench 118. An inner wall oxide film 121 is formed on the sidewall surface and the bottom surface of the trench 118. A trench isolation film 122 is formed so as to fill the interior of trench 118 on inner wall oxide film 121. A top portion of trench isolation insulating film 122 is formed so as to project above the top surface of semiconductor substrate 101.

There is formed an extended portion 120 of nitride region 119 formed on the sidewall and bottom of trench 118 along a peripheral edge portion of an element formation region which is a region surrounded with trench isolation insulation film 122 on the main surface of semiconductor substrate 101. Tunnel oxide film 103 is formed on the element formation region in the main surface of the semiconductor substrate 101. Tunnel oxide film 103 at a peripheral edge portion 128 thereof (a portion of tunnel oxide film 103 on extended portion 120) is thinner than at central portion 116 thereof. This is because as shown in a fabrication process described later, extended portion 120, which is a nitride region, has been formed on the main surface portion of the semiconductor substrate 101 when tunnel oxide film 103 is formed thereon, therefore, a formation speed of tunnel oxide film 103 on extended portion 120 is smaller than on the other region.

Note that, a structure in the upper layer side above tunnel oxide film 103 is fundamentally similar to that of the non-volatile semiconductor memory device shown in FIGS. 20 and 21.

FIGS. 27 to 30 are schematic sectional views for describing a method of manufacturing the non-volatile semiconductor memory device shown in FIG. 26. Referring to FIGS. 27 to 30, description will be given of a method of manufacturing the non-volatile semiconductor memory device shown in FIG. 26.

First of all, silicon oxide film 111 (see FIG. 27) is formed on the main surface of semiconductor substrate 101. Silicon nitride film 112 is formed on silicon oxide film 111. A resist film (not shown) having a pattern for openings is formed on silicon nitride film 112 with the openings located on regions where trenches 118 (see FIG. 27) are formed. Silicon nitride film 112 is partly removed with the resist film as a mask. Thereafter, the resist film is removed.

Silicon oxide film 111 and semiconductor substrate 101 are partly etched off with patterned silicon nitride film 112 as a mask, with the result that trenches 118 as shown in FIG. 27 are formed. Thereafter, inner wall oxide film 121 (see FIG. 27) is formed on the sidewall and bottom of trenches 118.

Then, by nitriding the sidewall and bottom wall of trench 118, nitride region 119 is formed. In such a way, a structure as shown in FIG. 27 is obtained. Note that the reason why nitride region 119 is formed is that crystal defects are prevented from occurring in semiconductor substrate 101 by a heat treatment subsequent to a step of forming a HDP (High Density Plasma)-CVD silicon oxide film, described later.

In formation of nitride region 119, a region of semiconductor substrate 101 under the peripheral edge portion of silicon oxide film 111 is also partly nitrided. As a result, in the region under the peripheral edge portion of silicon oxide film 111, there is formed extended portion 120 by advancement of a nitride region partly into the main surface of semiconductor substrate 101.

Then, a HDP-CVD silicon oxide film (an oxide formed with a HDP-CVD method) is formed so as to fill the interior of trench 118. Thereafter, a resist film (not shown) having a pattern is formed on the HDP-CVD silicon oxide film. The HDP-CVD silicon oxide film is partly etched off with the resist film as a mask. As a result, a depression is formed in a region of HDP-CVD silicon oxide film on silicon nitride film 112. Thereafter the resist film is removed.

Then, top portions of the HDP-CVD silicon oxide film and silicon nitride film 112 are polished off using a CMP (Chemical Mechanical Polishing) method, thereby planarizing the top surface of the HDP-CVD silicon oxide film. Thereafter, silicon nitride film 112 is removed to obtain a structure as shown in FIG. 28.

Subsequently, as shown in FIG. 29, silicon oxide film 111 is removed by wet etching. A sacrifice oxide film (not shown) is formed on the main surface of semiconductor substrate 101, followed by a step of implantation for forming impurity regions such as a source region and a drain region. Thereafter, the sacrifice oxide film is removed by wet etching.

Similar to a step shown in FIG. 25, tunnel oxide film 103 is formed on the main surface of semiconductor 101 using a wet oxidation method. At this time, a forming speed of tunnel oxide film 103 on extended region 120, which is a nitride region, is smaller than that of the tunnel oxide film 130 on the other region. For this reason, tunnel oxide film 103 on extended portion 120 is thinner than on the other region (central portion 116 of tunnel oxide film 103) with the result of a structure fabricated as shown in FIG. 30.

Thereafter, sequentially formed on tunnel oxide film 103 are floating gate electrodes 104a to 104c, ONO film 105, polysilicon film 106, tungsten silicide film 107 and oxide film 108 and so on in that order, thus obtaining the non-volatile semiconductor memory device shown in FIG. 26.

There have been problems, as described below, in the prior art non-volatile semiconductor memory devices described above.

That is, in the non-volatile semiconductor memory device shown in FIG. 20, since tunnel oxide film 103 on step section 115 is thinner than on the other region, a threshold voltage of the non-volatile semiconductor memory device has a chance to be different from a design value. Furthermore, in the non-volatile semiconductor device shown in FIG. 26 as well, tunnel oxide film 103 on extended portion 120 is thinner than on the other region due to the presence of extended portion 120, which is a nitride region. As a result, a threshold voltage of the non-volatile semiconductor memory device in the latter case also has a chance to be different from a design value.

On the other hand, for example, in a case where a non-volatile semiconductor memory device is a DINOR flash memory, a problem has been produced due to a defect such as gate disturb. Furthermore, in an NOR flash memory, since a threshold voltage distribution in erase operation is wider than in a design, an electrical characteristic has had a chance to be deteriorated. In such a manner, in a prior art non-volatile semiconductor memory device, a problem has had a chance to occur due to a deteriorated electrical characteristic caused by local thinning of tunnel oxide film 103.

### SUMMARY OF THE INVENTION

It is an object of the present invention to provide a method of manufacturing a semiconductor device capable of preventing deterioration in electrical characteristic thereof.

In one aspect of the present invention, a method of manufacturing a semiconductor device is provided. The semiconductor device includes: a semiconductor substrate having an element formation region and an element isolation region abutting on the element formation region, a step section being formed at a boundary portion between the element formation region and the element isolation region on a main surface of the semiconductor substrate; an insulating film including an oxide film formed so as to cover the element formation region and in addition, extend over the step section on the main surface of the semiconductor substrate; and a gate electrode formed on the insulating film. The thickness of the insulating film on the element formation region may be almost equal to that of the insulating film on the step section. The method includes: a step of forming the step section on the main surface of the semiconductor substrate; and a step of forming the oxide film on the main surface of the semiconductor substrate using an active oxygen.

With such a process adopted, since the active oxygen has an extremely strong oxidizing capability, an oxide film can be formed to an almost uniform thickness on a main surface of a semiconductor substrate without receiving any influence of the presence of a step section thereon even when the step section is present on the main surface of a semiconductor substrate on which the oxide film is formed. In a semiconductor device fabricated using the method described above, since the insulating film is not locally thinner on the step section, as compared with other regions, a phenomenon can be prevented from occurring that when a voltage is applied to the gate electrode, an electric field strength in the insulating film on the step section is locally enhanced. In a case where an insulating film is used as, for example, a tunnel insulating film of a non-volatile semiconductor memory device, it can be prevented that a threshold voltage of the non-volatile semiconductor memory device or the like characteristic thereof changes due to a local variation in thickness of the insulating film. That is, an electrical characteristic of a semiconductor device is prevented from being deteriorated.

The term “almost equal” in the above one aspect of the invention means that a difference between a thickness of the insulating film on the element forming region and the thickness of the insulating film on the step section is preferably less than 20%, more preferably less than 10%, in particular less than 5%, relative to the thickness of the insulating film on the element formation region.

In another aspect of the present invention, a method of manufacturing a semiconductor device is provided. The semiconductor device includes: a semiconductor substrate having a main surface, the main surface of the semiconductor substrate including one region, which is nitrided, and the other region, which is not nitrided and abutting on the one region; an insulating film including an oxide film formed on the one region and the other region of the main surface of the semiconductor substrate; and a gate electrode formed on the insulating film. The thickness of the insulating film on the one region may be almost equal to that of the insulating film on the other region. The method includes: a step of forming the one region by partially nitriding the main surface of the semiconductor substrate; and a step of forming the oxide film on the main surface of the semiconductor substrate using an active oxygen.

With such a process adopted, since the active oxygen has an extremely strong oxidizing capability, an oxide film can be formed to an almost uniform thickness on a main surface of a semiconductor substrate without receiving any influence of the presence of a nitrided region thereon even when the nitrided region is present on the main surface of a semiconductor substrate on which the oxide film is formed. In a semiconductor device fabricated using the method described above, since an insulating film is not locally thinner on one region, which is a nitrided region, a phenomenon can be prevented from occurring that when a voltage is applied to the gate electrode, an electric field strength is locally enhanced in the insulating film on the one region. For this reason, in a case where an insulating film is used, for example, as a tunnel insulating film of a non-volatile semiconductor device, it is prevented that a threshold voltage of the non-volatile semiconductor memory device changes due to a local variation in thickness of the insulating film. That is, an electrical characteristic of a semiconductor device is prevented from being deteriorated.

The term “almost equal” in the above another aspect of the invention means that a difference between a thickness of the insulating film on the one region and the thickness of the insulating film on the other region is preferably less than 20%, more preferably less than 10%, in particular less than 5%, relative to the thickness of the insulating film on the other region.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view showing a first embodiment of a semiconductor device according to the present invention;

FIG. 2 is a schematic sectional view taken on line II-II of FIG. 1;

FIGS. 3 to 7 are schematic sectional views for describing a first to fifth steps, respectively, of a manufacturing process of the semiconductor device shown in FIGS. 1 and 2;

FIG. 8 is a schematic partly enlarged sectional view showing a step section of the semiconductor device shown in FIG. 7;

FIG. 9 is a schematic sectional view for describing a sixth step of the manufacturing process of the semiconductor device shown in FIGS. 1 and 2;

FIG. 10 is a schematic sectional view showing a second embodiment of a semiconductor device according to the present invention;

FIGS. 11 to 19 are schematic sectional views for describing a first to ninth steps, respectively, of a manufacturing process of the semiconductor device shown in FIG. 10;

FIG. 20 is a schematic sectional view showing a prior art non-volatile semiconductor memory device;

FIG. 21 is a schematic partly enlarged sectional view of the non-volatile semiconductor memory device shown in FIG. 20;

FIGS. 22 to 25 are schematic sectional views for describing a first to fourth steps, respectively, of a manufacturing process for the non-volatile semiconductor memory device shown in FIGS. 20 and 21;

FIG. 26 is a schematic sectional view showing another example of prior art non-volatile semiconductor memory device; and

FIGS. 27 to 30 are schematic sectional views for describing a first to fourth steps, respectively, of a manufacturing process of the non-volatile semiconductor memory device shown in FIG. 26.

### DESCRIPTION OF THE PREFERRED EMBODIMENTS

Description will be given of embodiments of the present invention based on the accompanying drawings. Note that the same reference numerals are attached to the same or corresponding constituents on the following figures and no description thereof is repeated.

(First Embodiment)

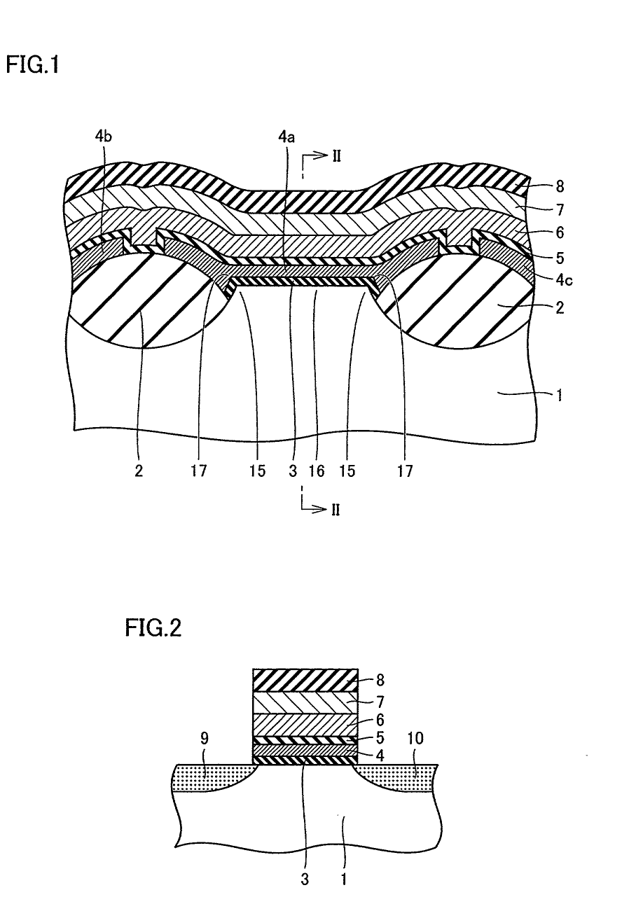

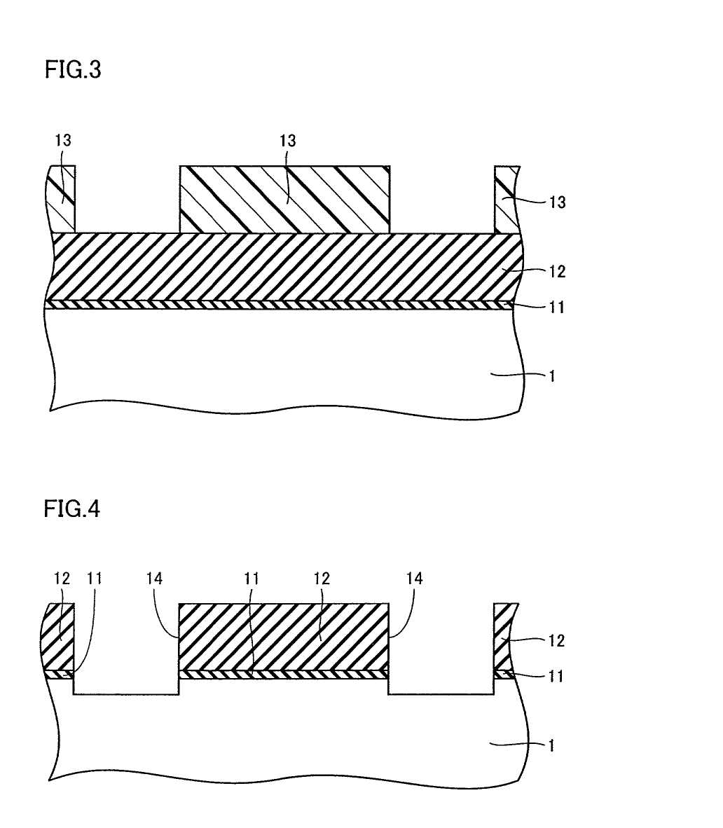

Referring to FIGS. 1 and 2, description will be given of a first embodiment of a semiconductor device according to the present invention.

Referring to FIGS. 1 and 2, the semiconductor device is a non-volatile semiconductor memory device and, to be concrete, is a DINOR or NOR flash memory. The semiconductor device is fabricated in an element formation region surrounded with an isolation insulating film 2 located in first and second element isolation regions on a main surface of a semiconductor substrate 1. The element formation region of semiconductor substrate 1 has a flat top surface (a flat section). Step sections 15 are formed at a boundary portion between the element forming region and isolation insulating film 2 on the main surface of semiconductor substrate 1. A tunnel oxide film 3 as an insulating film is formed on the main surface of semiconductor substrate 1. Tunnel oxide film 3 is formed so as to cover the flat section on the main surface of semiconductor substrate 1 and extend over step sections 15. A thickness of tunnel oxide film 3 is on the order in the range of 30 nm to 50 nm.

A floating gate electrode 4a is formed so as to cover tunnel oxide film 3 and extend to near the top portions of isolation insulating film 2. Furthermore, a tunnel oxide film, though not shown, is also formed, on regions opposite to the region where tunnel oxide film 3 is formed with isolation insulating film 2 interposing therebetween on the main surface of semiconductor substrate 1 and floating gate electrodes 4b and 4c are formed on the tunnel oxide film.

An ONO film 5 is formed on floating gate electrodes 4a to 4c. ONO film 5 is a stacked film composed of a lower oxide film, a nitride film formed on the lower oxide film and an upper oxide film formed on the nitride film in that order. A polysilicon film 6 is formed on ONO film 5. A tungsten silicide film 7 is formed on polysilicon film 6. A control gate is constituted of polysilicon film 6 and tungsten silicide film 7. An oxide film 8 is formed on tungsten silicide film 7 using a CVD method.

As shown in FIG. 2, on the main surface of the semiconductor substrate 1, a source region 9 and a drain region 10 are formed at opposite positions with the region where tunnel oxide film 3 is formed interposing therebetween.

In the semiconductor device shown in FIGS. 1 and 2, a thickness of tunnel oxide film 3 at a central section 16 is almost equal to a thickness of tunnel oxide film 3 at a peripheral edge portion 17 (a portion on step section 15).

With such a structure adopted, since tunnel oxide film 3 as an insulating film has no locally thinner portion on two step portions 15, a phenomenon can be prevented from occurring that when a voltage is applied to the control gate electrode, an electric field strength in tunnel oxide film 3 on step section 15 is locally enhanced. For this reason, it can be prevented that a threshold voltage or the like of a semiconductor device changes due to a local variation in thickness of tunnel oxide film 3. That is, an electrical characteristic of the semiconductor device can be prevented from being deteriorated.

Referring to FIGS. 3 to 9, description will be given of a method of manufacturing the semiconductor device shown in FIGS. 1 and 2.

As shown in FIG. 3, a silicon oxide film 11 is formed on the main surface of semiconductor substrate 1. A thickness of the silicon oxide film ranges, for example, from 30 to 50 nm. A silicon nitride film 12 is formed on silicon oxide film 11. A thickness of silicon nitride film 12 ranges, for example, from 30 to 150 nm. A resist film 13 having a pattern for openings is formed on silicon nitride film 12 with the openings on regions where isolation insulating films 2 are formed using a photolithographic processing technique.

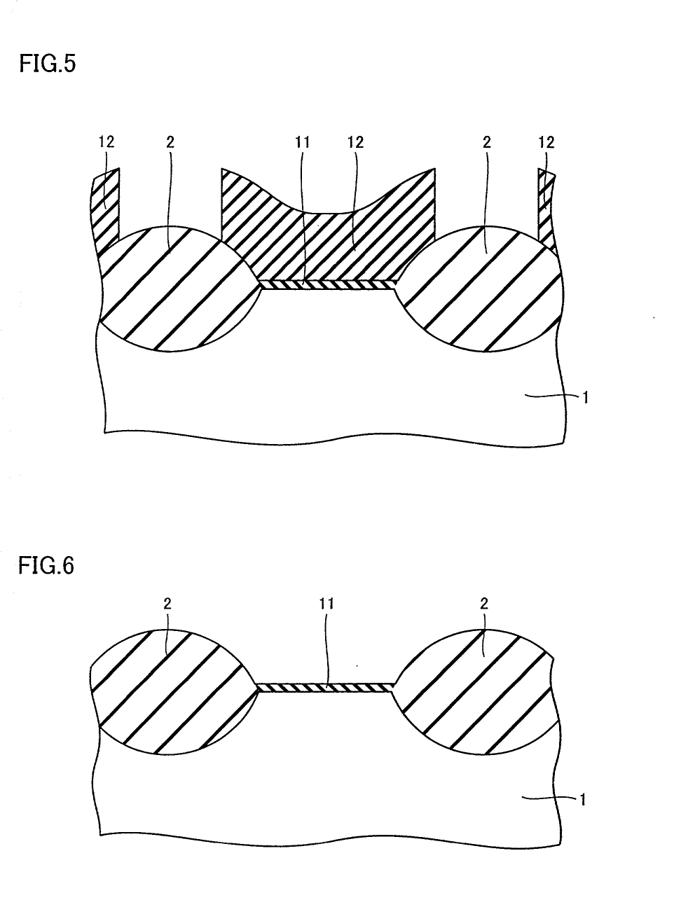

Then, silicon nitride film 12 and silicon oxide film 11 are partly removed by etching using resist film 13 as a mask. As a result, openings 14 (see FIG. 4) are formed in silicon nitride film 12 and silicon oxide film 11. Thereafter, resist film 13 is removed. A resulting structure is as shown in FIG. 4. Note that in the above etching step, the top surface of semiconductor substrate 1 is also partly removed at the bottom of opening 14 by over-etching.

Then, as shown in FIG. 5, isolation insulating film 2 is formed at the bottom of opening 14 by oxidizing an exposed surface of semiconductor substrate 1 there. In this step, as shown in FIG. 5, since isolation insulating film 2 grows up into under a lower end portion of silicon nitride film 12, the lower end portion of silicon nitride film 12 is shaped so as sit on an upper end portion of isolation insulating film 2.

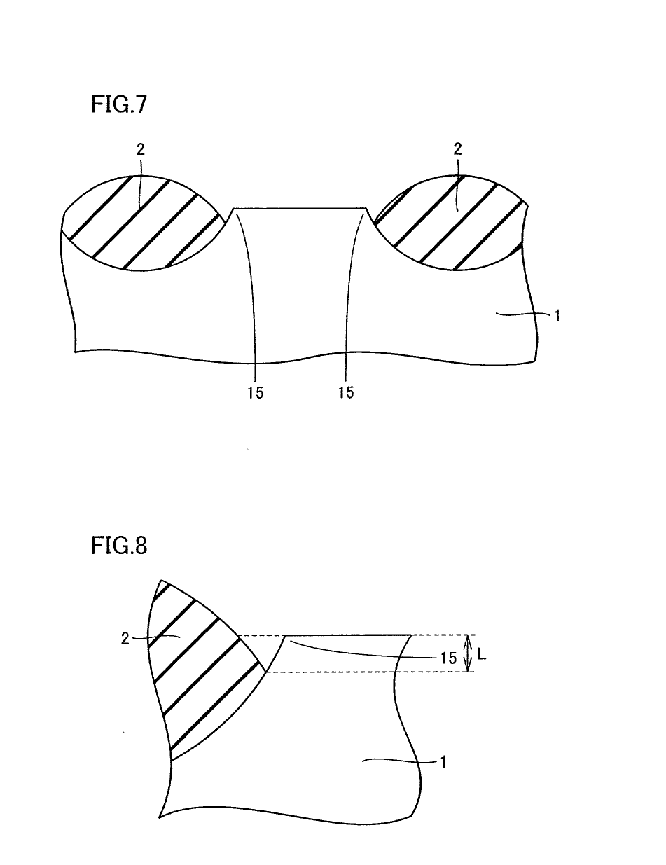

Thereafter, as shown in FIG. 6, silicon nitride film 12 (see FIG. 5) having been used as a mask is removed.

Then, as shown in FIG. 7, silicon oxide film 11 (see FIG. 6) is removed by wet etching. At this time, the top surface of isolation insulating film 2 is also partly removed by the wet etching simultaneously with the removal of silicon oxide film 11. Therefore, as shown in FIG. 7, by removing the surface of isolation insulating film 2, step section 15 comes to be formed at a boundary portion between the element formation region and the element isolation region in which isolation insulating film 2 is present, on the main surface of semiconductor substrate 1. In the removal of silicon oxide film 11, the etching is performed till a height L of step section 15 (see FIG. 8) reaches a value of the order of 10 nm. FIG. 8 is a schematic partly enlarged sectional view showing the step section of the semiconductor device shown in FIG. 7.

Thereafter, a sacrifice film (not shown) is formed for protection of the main surface of semiconductor substrate 1. Then, a conductive impurity is implanted into the main surface of semiconductor substrate 1 in order to form a source region 9, a drain region 10 and others. After such implantation of the conductive impurity, the above sacrifice oxide film is removed by wet etching.

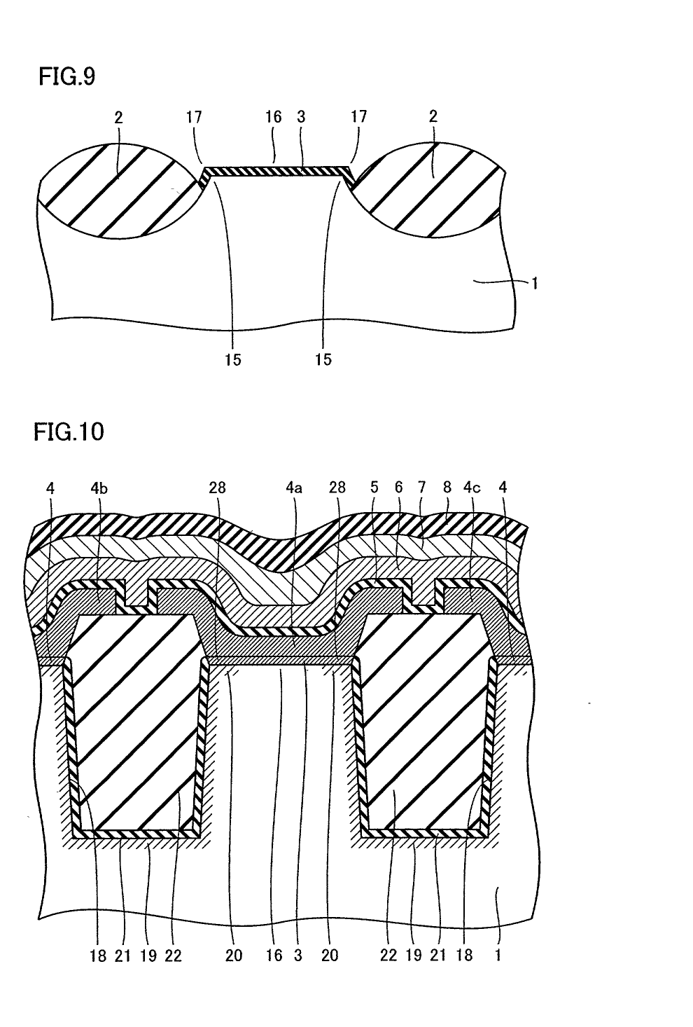

As shown in FIG. 9, tunnel oxide film 3 is formed using an active oxygen on the main surface of semiconductor substrate 1. As process conditions for the step, those described below, for example, can be adopted. That is, a reaction gas supplied into a chamber, in which semiconductor substrate 1 is placed in oxidation performed, is composed of oxygen gas (O₂) and hydrogen gas (H₂). A flow rate of oxygen gas is 9.5 l/min and a flow rate of hydrogen gas is 0.5 l/min. Furthermore, a heating temperature is in the range of from 1000 to 1050° C. and a heating time ranges from 1 min to 2 min. As a result, an active oxygen can be generated in the interior of the chamber. Since an active oxygen has an extremely strong oxidizing capability, tunnel oxide film 3 can be formed all over the surface of semiconductor substrate 1 to near uniformity in thickness regardless of a local surface state of the main surface of semiconductor substrate 1. Hence, a thickness at central section 16 of tunnel oxide film 3 can be made almost equal to a thickness at peripheral edge portion 17 of tunnel oxide film 3.

Note that in a process step of forming tunnel oxide film 3, as a heating method, there may be used an RTP (Rapid Thermal Process) or any of the like other heating methods. Furthermore, as the reaction gas, there may be used N₂O gas or a mixture of NO gas and oxygen gas. Moreover, an active oxygen may be generated by a plasma generated in the interior of the chamber. Combinations of a heating method and a reaction gas can be changed in any convenient way. Furthermore, as a reaction gas used in generation of an active oxygen using a plasma, the above reaction gases can be used in a proper manner.

Thereafter, formed sequentially on tunnel oxide film 3 are floating gate electrodes 4a to 4c, ONO film 5, polysilicon film 6, tungsten silicide film 7 and oxide film 8 in that order, thereby enabling the semiconductor device shown in FIGS. 1 and 2 to be achieved.

(Second Embodiment)

Referring to FIG. 10, description will be given of a second embodiment of a semiconductor device according to the present invention, wherein FIG. 10 corresponds to FIG. 1.

Referring to FIG. 10, a semiconductor device has a structure fundamentally similar to that of the semiconductor device shown in FIGS. 1 and 2, with a difference in a structure of an element isolation region. That is, in the semiconductor device shown in FIGS. 1 and 2, there is provided isolation insulating film 2 formed using a LOCOS method in the element isolation region, while in the semiconductor device shown in FIG. 10, a so-called trench isolation structure is adopted in the element isolation region. That is, a trench 18 is formed in semiconductor substrate 1 so as to abut on the element formation region.

A nitride region 19 is formed in regions of the semiconductor substrate constituting a sidewall surface and bottom surface of trench 18. An inner wall oxide film 21 is formed on the sidewall and the bottom of trench 18. A trench isolation insulating film 22 is formed on inner wall oxide film 21 so as to fill the interior of trench 18. A top portion of trench isolation insulating film 22 is formed so as to project above the top surface of semiconductor substrate 1.

Tunnel oxide film 3 is formed on the main surface of semiconductor substrate 1 in the element formation region, which is a region surrounded with trench isolation insulating film 22. Extended portions 20 are formed by extending a nitride region formed on the sidewall of trench 18 into the main surface of semiconductor substrate 1, in two peripheral edge portions of the element formation region surrounded with trench isolation insulating film 22 (regions abutting on trench isolation insulating film 22). A thickness at central section 16 of tunnel insulating film 3 is almost equal to thicknesses at peripheral edge portions 28 of tunnel oxide film 3 (tunnel insulating film 3 on extended portions 20 as first and second regions). A structure of the upper layer side above tunnel oxide film 3 is fundamentally similar to that in the semiconductor device shown in FIGS. 1 and 2.

With such a structure adopted, since tunnel oxide film 3 as an insulating film has no locally thinner portion in peripheral edge portions 28 on extended portions 20 as one region, which is a nitride region, a phenomenon can be prevented from occurring that when a voltage is applied to the control gate electrode, an electric field strength in tunnel oxide film 3 on extended portion 20 is locally enhanced. For this reason, it can be prevented that a threshold voltage of a semiconductor device changes due to a local variation in thickness of tunnel oxide film 3. That is, an electrical characteristic of the semiconductor device can be prevented from being deteriorated.

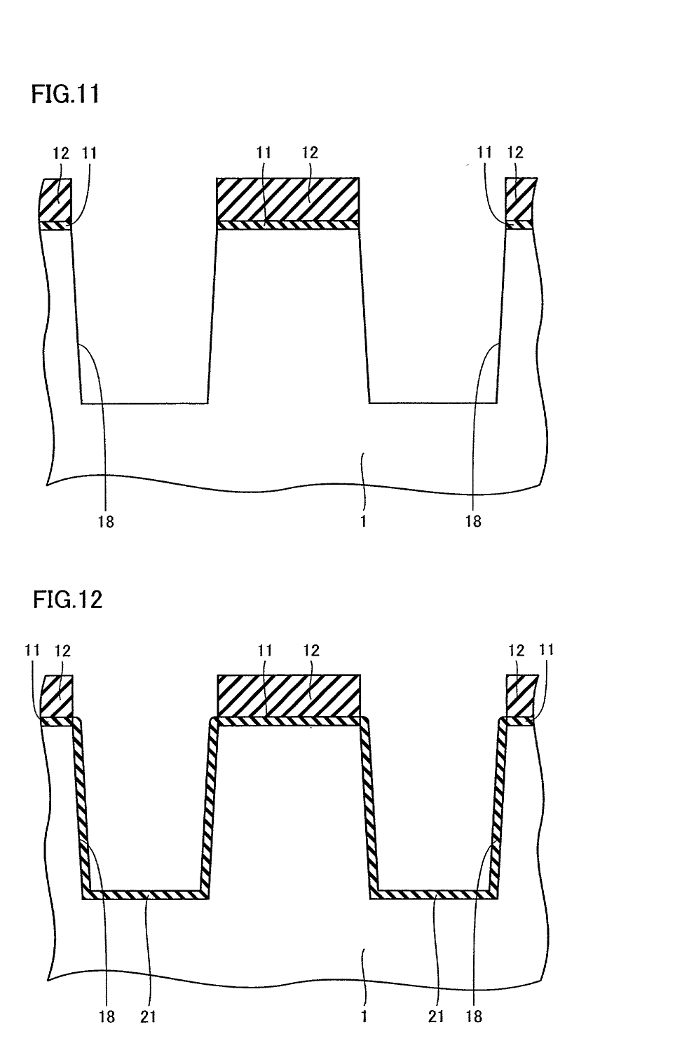

Referring to FIGS. 11 to 19, description will be given of a manufacturing process for a semiconductor device shown in FIG. 10.

Silicon oxide film 11 is formed on the main surface of semiconductor substrate 1 similar to the step shown in FIG. 3. Silicon nitride film 12 is formed on silicon oxide film 11. A resist film (not shown) having a pattern for openings is formed on silicon nitride film 12 with the openings located on regions where trenches 18 (see FIG. 11) are formed. Silicon nitride film 12 and silicon oxide film 11 are partly removed with the resist film as a mask. Thereafter, the resist film is removed. Semiconductor substrate 1 is partly etched off with patterned silicon nitride film 12 as a mask, with the result that trench 18 (see FIG. 11) is formed. In such a way, a structure as shown in FIG. 11 is obtained.

Thereafter, inner wall oxide film 21 is formed on the sidewall and bottom of trench 18 to a thickness ranging, for example, from 30 to 50 nm.

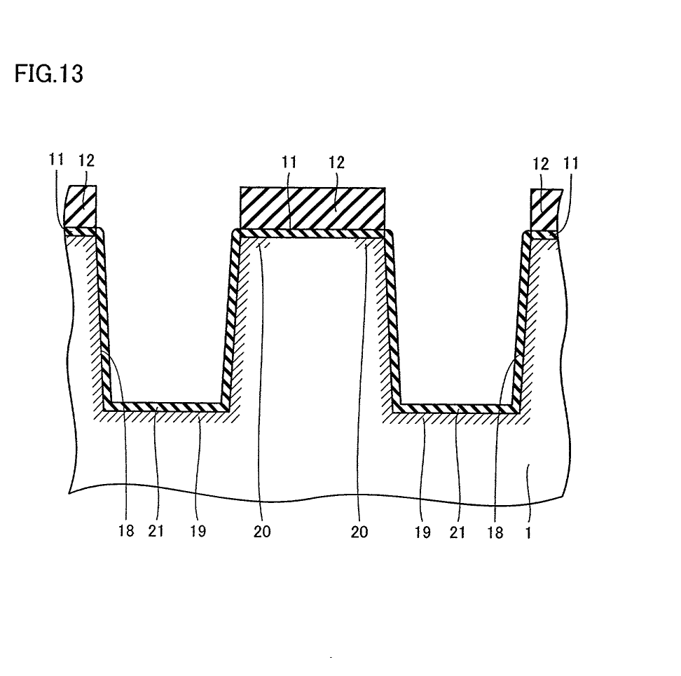

Then, as shown in FIG. 13, by nitriding the sidewall and bottom wall of trench 18, nitride region 19 is formed. The reason why nitride region 19 is formed in such a way is that suppression is intended on generation of crystal defects in semiconductor substrate 1 that would otherwise occur by a heat treatment subsequent to the step of forming a HDP-CVD silicon oxide film described later. In the nitriding step, by also partly nitriding a region of semiconductor substrate 1 under the peripheral edge portion of silicon oxide film 11, extended portion 20, which is a nitride region, is formed.

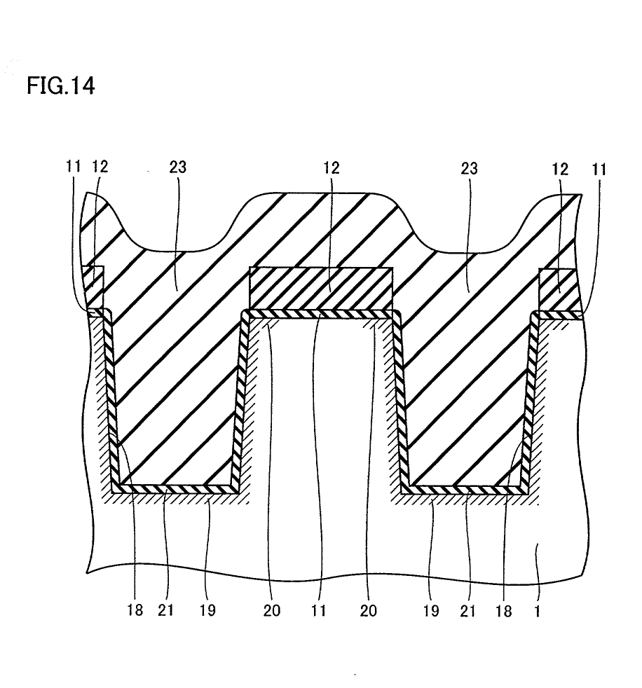

Then, HDP-CVD silicon oxide film 23 is formed so as to fill the interior of trench 18. As a result, a structure as shown in FIG. 14 is obtained.

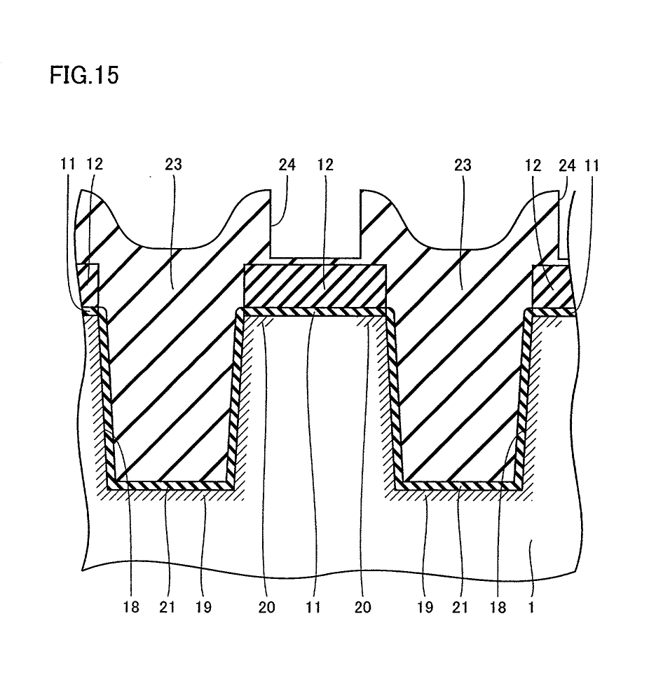

There is formed a resist film (not shown) having a pattern on HDP-CVD silicon oxide film 23. An opening of the pattern is formed on the resist film at a region above silicon nitride film 12. HDP-CVD silicon oxide film 23 is partly etched off with the resist film as a mask. As a result, a depression 24 is formed in a region of HDP-CVD silicon oxide film 23 on silicon nitride film 12. Thereafter, the resist film is removed, resulting in a structure as shown in FIG. 15.

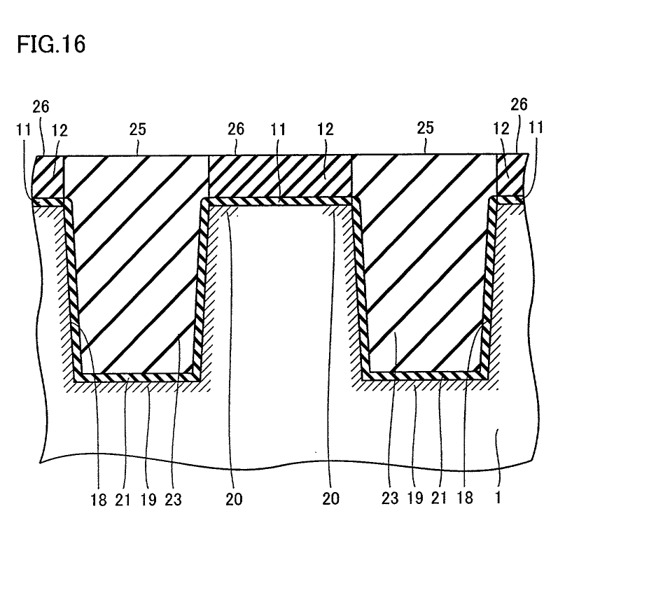

Then, the top portions of HDP-CVD silicon oxide film 23 and silicon nitride film 12 are polished off using a chemical mechanical polishing method (a CMP method), thereby planarizing the top surface of HDP-CVD silicon oxide film 23. As a result, a structure as shown in FIG. 16 is obtained.

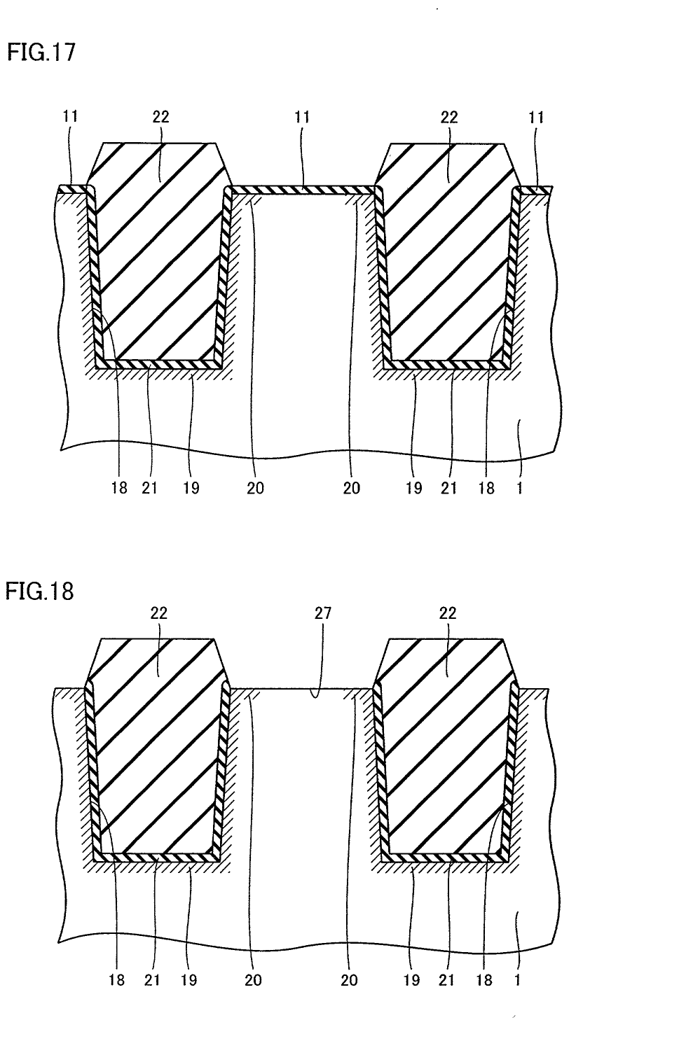

Thereafter, by removing silicon nitride film 12, a structure as shown in FIG. 17 is obtained. Then, as shown in FIG. 18, silicon oxide film 11 is removed by wet etching. As a result, main surface 27 of semiconductor substrate 1 is exposed.

Then, after a sacrifice oxide film (not shown) is formed on the main surface of semiconductor substrate 1, an implantation step is performed for forming impurity diffused regions such as a source region 9 and a drain region 10. Subsequently, the sacrifice oxide film is removed by wet etching.

Then, similar to the step shown in FIG. 9, tunnel oxide film 3 is formed on the main surface of semiconductor substrate 1 using an active oxygen. That is, process conditions similar to those described in FIG. 9 can be used as process conditions for the above step of forming tunnel oxide film 3 using an active oxygen. In this case, while an active oxygen is generated in the chamber as a reaction vessel, the active oxygen has an extremely strong oxidizing capability. For this reason, tunnel oxide film 3 having an almost uniform thickness can be formed on regions each different in state of the main surface of semiconductor substrate 1 from others (that is, a region in which no extended portion 20 of nitride region exists and a region in which the extended portion 20 exists).

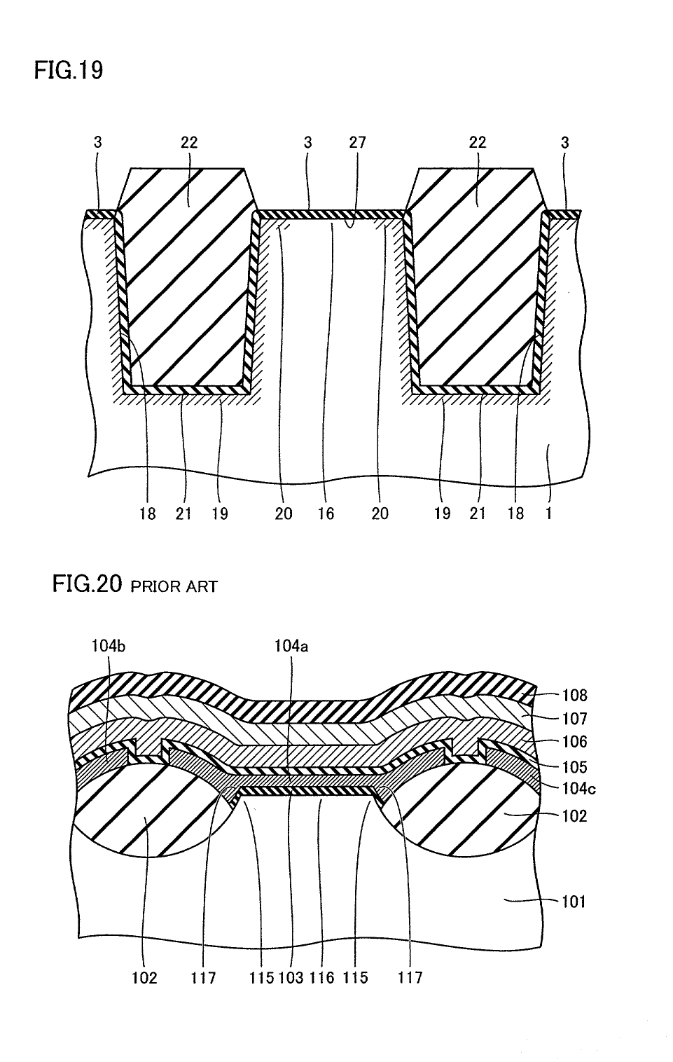

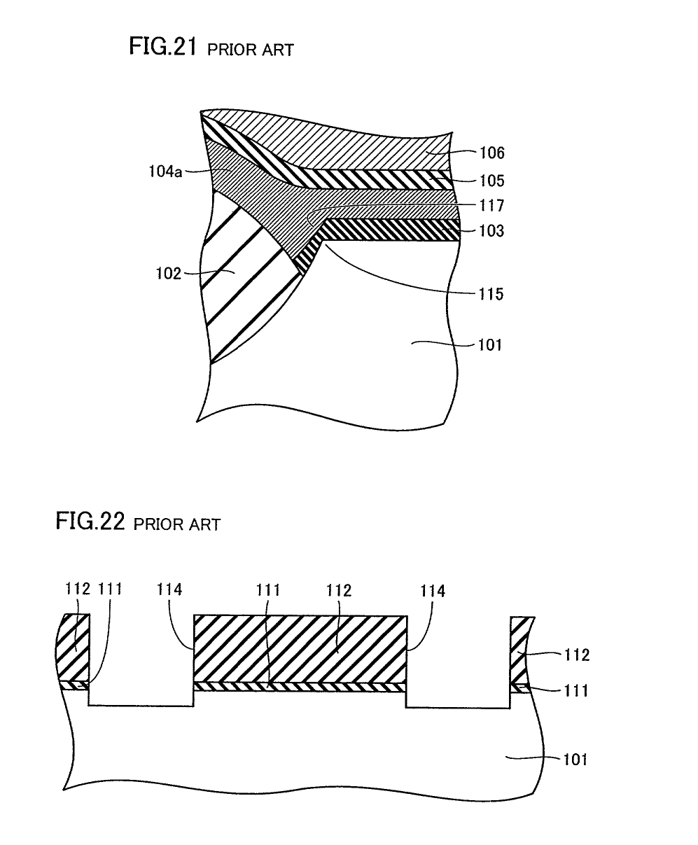

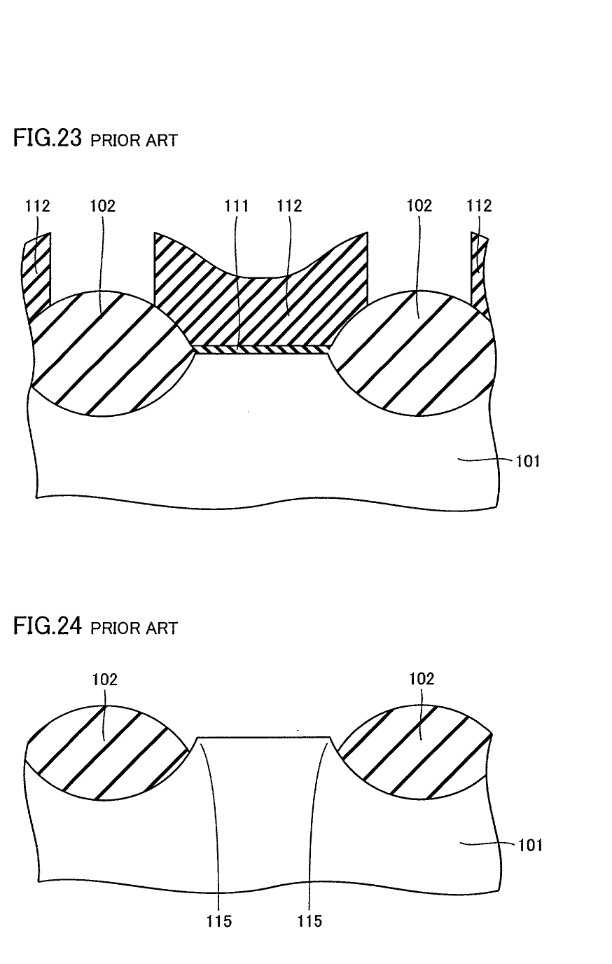

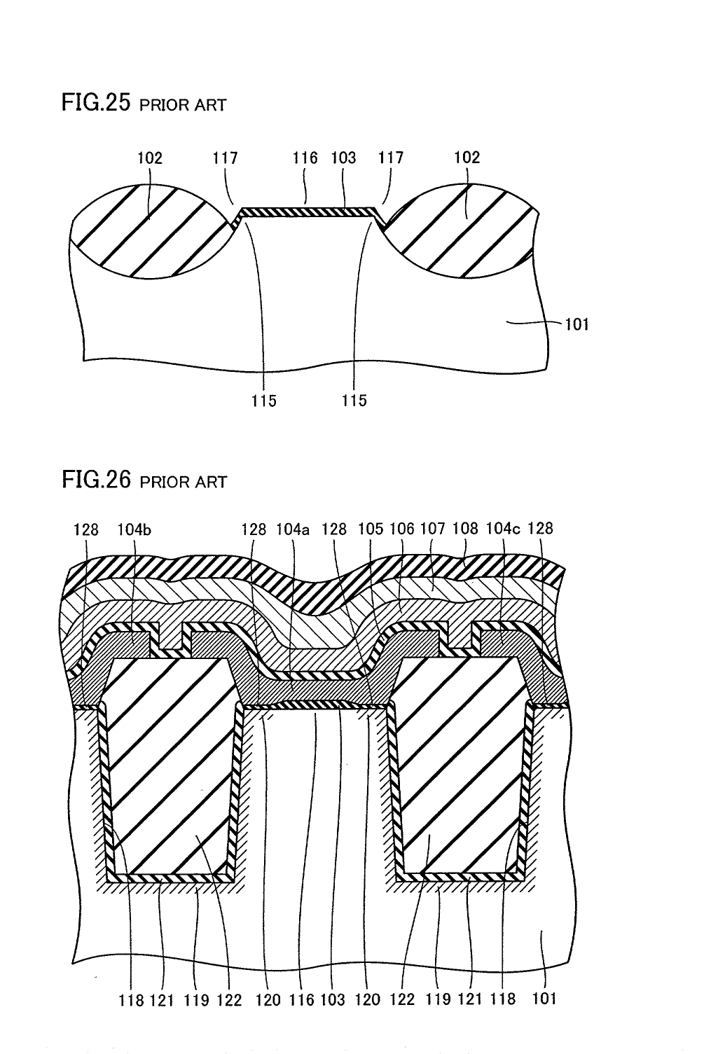

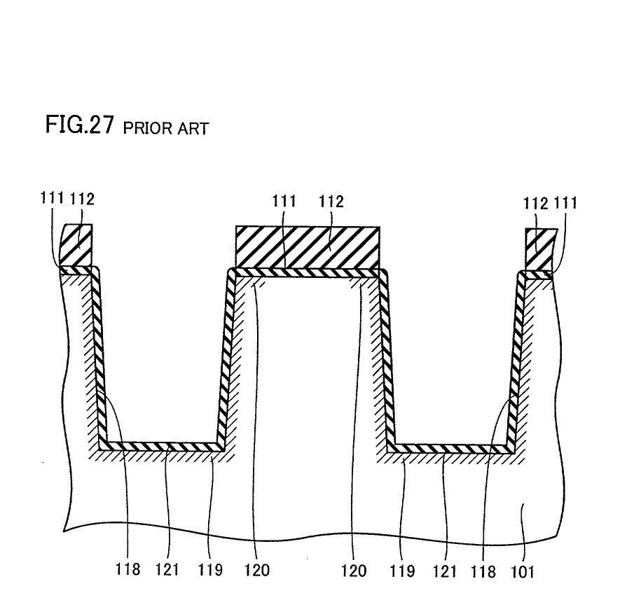

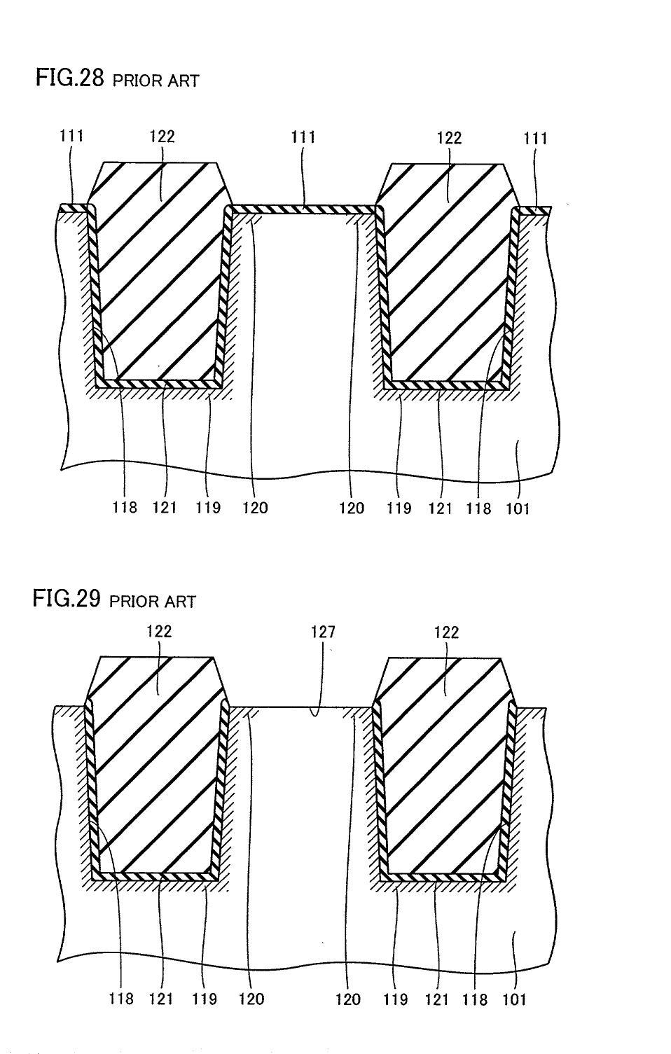

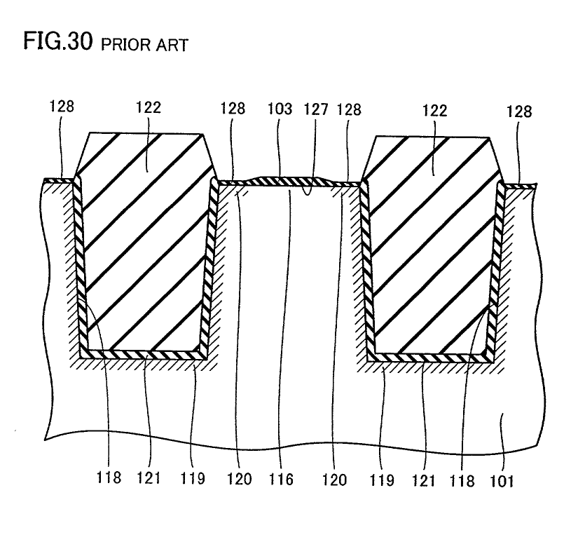

As a result, a structure as shown in FIG. 19 is obtained. Tunnel oxide film 3 on extended portion 20 of the nitride region has a thickness almost equal to that of tunnel oxide film 3 at the central section thereof.

Note that in the step of forming tunnel oxide film 3, there may be used an RTP (a Rapid Thermal Process) or any of other heating methods as a heating method, similar to the first embodiment of the present invention. Furthermore, as a reaction gas, N₂O gas or a mixture of NO gas and oxygen gas may be used. Moreover, an active oxygen may be generated by use of a plasma in the interior of the chamber. A combination of a heating method and a reaction gas can be properly selected from the above heating methods and the reaction gases. Furthermore, any of the above reaction gases can be properly used as a reaction gas for use in generation of an active oxygen in a plasma.

Subsequently, sequentially formed on tunnel oxide film 3 are floating gate electrodes 4a to 4c, ONO film, polysilicon film 6, tungsten silicide film 7, oxide film 8 and so on in that order, thereby, enabling the semiconductor device shown in FIG. 10 to be obtained.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device, said semiconductor device including: a semiconductor substrate having an element formation region and an element isolation region abutting on said element formation region, a step section being formed at a boundary portion between said element formation region and said element isolation region on a main surface of said semiconductor substrate; an insulating film including an oxide film formed so as to cover said element formation region and in addition, extend over said step section on said main surface of said semiconductor substrate; and a gate electrode formed on said insulating film, said method comprising the steps of:
forming said step section on said main surface of said semiconductor substrate; and
forming said oxide film on said main surface of said semiconductor substrate using an active oxygen.

2. The method of manufacturing a semiconductor device according to claim 1, wherein
said semiconductor device is a nonvolatile semiconductor device,
said gate electrode is a floating gate electrode of said non-volatile semiconductor device, and
said insulating film is a tunnel insulating film located between said semiconductor substrate and said floating gate electrode.

3. A method of manufacturing a semiconductor device, said semiconductor device including: a semiconductor substrate having a main surface, said main surface of said semiconductor substrate including one region, which is nitrided, and the other region, which is not nitrided and abutting on the one region; an insulating film including an oxide film formed on said one region and said other region of said main surface of said semiconductor substrate; and a gate electrode formed on said insulating film, said method comprising the steps of:
forming said one region by partially nitriding said main surface of said semiconductor substrate; and
forming said oxide film on said main surface of said semiconductor substrate using an active oxygen.

4. The method of manufacturing a semiconductor device according to claim 3, further comprising the steps of:
forming a trench in a region opposite to said other region with said one region interposing therebetween on said main surface of said semiconductor substrate;
forming an inner wall oxide film on an inner wall of said trench; and
forming an isolation insulating film to fill said trench, wherein
said step of forming said one region is performed after said step of forming said inner wall oxide film and before said step of forming said isolation insulating film.

5. The method of manufacturing a semiconductor device according to claim 4, wherein
said semiconductor device is a non-volatile semiconductor device,
said gate electrode is a floating gate electrode of said non-volatile semiconductor device, and
said insulating film is a tunnel insulating film located between said semiconductor substrate and said floating gate electrode.
